(19) United States
(12) Patent Application Publication
(10) Pub. No.: US 2021/0245245 A1
(43) Pub. Date: Aug. 12, 2021

(54) COMPOSITE METAL MATERIAL, METHOD FOR PRODUCING SAME, AND ELECTRONIC DEVICE USING COMPOSITE METAL MATERIAL

(71) Applicant: HITACHI, LTD., Tokyo (JP)

(72) Inventors: Tomotake TOHEI, Tokyo (JP); Osamu IKEDA, Tokyo (JP); Kenichiro KUNITOMO, Tokyo (JP)

(73) Assignee: HITACHI, LTD., Tokyo (JP)

(21) Appl. No.: 16/972,317

(22) PCT Filed: Apr. 12, 2019
(86) PCT No.: PCT/JP2019/016063

§ 371 Date: Dec. 4, 2020

(30) Foreign Application Priority Data
Jul. 25, 2018 (JP) 2018-139530

(51) Int. Cl. B22F 7/02; H01L 23/373; H01L 21/48; C22C 38/00; C22C 9/00; B22F 3/105

(52) U.S. Cl. CPC B22F 7/02; H01L 23/3735; H01L 21/4878; B22F 2003/1051; C22C 9/00; B22F 3/105; C22C 38/00

(57) ABSTRACT

The present invention provides: a composite metal material which is able to be controlled in terms of strength, thermal conductivity and thermal expansion amount; and a method for producing this composite metal material. A composite metal material according to the present invention has a Cu-rich phase and an Fe-rich phase; and this composite metal material has a composite metal phase wherein Fe-rich phases are independently dispersed in a Cu-rich phase. The Cu-rich phase has a Cu content of more than 85 wt %; and each Fe-rich phase has an Fe content of more than 50 wt %.

### TECHNICAL FIELD

The present invention is a technique relating to a novel composite metal material.

### BACKGROUND ART

As a field in which excellent thermal conductivity is required, there are electronic devices. For example, there is a power semiconductor such as an Insulated Gate Bipolar Transistor (IGBT) used for power conversion. Since the heat dissipation of the semiconductor chip tends to increase along with the increase of the capacity and the increase of the speed, the heat dissipation of the power semiconductor is important. As a known technique for the heat dissipation structure, a structure in which Cu (393 W/m·k) having a high thermal conductivity is used as a heat sink and a semiconductor chip and a heat sink are bonded is a general structure. In these heat dissipation structures, an electronic device to which a semiconductor chip is bonded has a concern that the semiconductor chip and the bonding portion may be destructed due to the thermal stress caused by the difference in thermal expansion of each member along with the heat generation of the semiconductor chip. In addition, for molds used not only in electronic devices but also in industrial applications, if a member having a high thermal conductivity can be used while maintaining the strength of the mold, it is possible to greatly contribute to the shortening of the tact of the mold product along with high cooling. Therefore, the composite metal material having desired strength and thermal conductivity has a possibility of exerting the effect thereof in wide technical fields besides the electronic devices.

As a background art of a composite metal material having excellent thermal conductivity for dissipating heat generated in an electronic component to the outside, for example, there is Patent Document 1. Patent Document 1 discloses that, after bonding a Cu matrix, a Cr—Cu alloy plate containing 30 mass % to 80 mass % of Cr, and a Cu plate, rolling is performed to form a laminated body of a Cr—Cu alloy and Cu.

### CITATION LIST

### Patent Document

Patent Document 1: JP 2001-196513 A

### SUMMARY OF THE INVENTION

### Problems to be Solved by the Invention

In Patent Document 1, by laminating an alloy made of Cr—Cu with respect to a high thermal conductivity and Cu, adjustment of the thermal expansion coefficient and the high thermal conductivity have been realized. However, in the case of Patent Document 1, since a laminated structure is formed by rolling, the metal structure of Cr and Cu in the Cr—Cu alloy is extended in the rolling direction during the rolling, so that a specific metal structure having anisotropy is formed. That is, in the case of Patent Document 1, the metal structure of Cr having a thermal conductivity lower than that of Cu is formed in a flat shape in the vertical direction with respect to the lamination direction, so that the thermal conductivity is impeded. In addition, in a case where the alloy described in Cited Document 1 is used for a mold or the like, it is important to be able to secure the strength, and the non-uniform strength having anisotropy leads to deterioration of reliability.

Therefore, an object of the present invention is to provide a composite metal material having an excellent composite effect by adjusting a metal structure in a composite metal, a method for producing the composite metal material, and an electronic device using the composite metal material.

### Solutions to Problems

As an example of a composite metal material for solving the above-described problems, there is a composite metal material having a Cu-rich phase and an Fe-rich phase, which has a composite metal phase in which the Fe-rich phases are independently dispersed in the Cu-rich phase.

In addition, as an example of an electronic device of the present invention, there are a composite metal material having a composite metal phase in which Fe-rich phases are independently dispersed in a Cu-rich phase and a semiconductor element mounted on the composite metal material.

In addition, as an example of a method for producing the composite metal material, there is a method for producing a composite metal material having a Cu-rich phase and an Fe-rich phase, in which the composite metal phase is formed by performing laser irradiation while supplying predetermined proportions of Cu powder and Fe-based alloy powder.

### Effects of the Invention

According to the present invention, it is possible to exhibit an excellent composite effect by adjusting a metal structure in a composite metal. As an example of the excellent composite effect, it is possible to provide a composite metal material having excellent thermal conductivity and a predetermined strength.

### BRIEF DESCRIPTION OF THE DRAWINGS

FIG. 1 is a photograph of high-magnification observation of a metal structure of a first layer made of a composite metal phase.

FIG. 2 is a photograph of low-magnification observation of the metal structure of the first layer made of the composite metal phase.

FIG. 3 is a photograph of high-magnification observation of a metal structure of a second layer made of the composite metal phase.

FIG. 4 is a photograph of low-magnification observation of the metal structure of the second layer made of the composite metal phase.

FIG. 5 is a photograph of high-magnification observation of a metal structure of a third layer made of the composite metal phase.

FIG. 6 is a photograph of low-magnification observation of the metal structure of the third layer made of the composite metal phase.

FIG. 7 is a cross-sectional observation photograph of a bonding interface between the first layer made of the composite metal phase and Cu.

FIG. 8 is a cross-sectional observation photograph of a bonding interface between the first layer and the second layer made of the composite metal phase.

FIG. 9 is a cross-sectional observation photograph of a bonding interface between the second layer and the third layer made of the composite metal phase.

FIGS. 10A to 10D is a diagram illustrating a producing process for forming the first layer made of the composite metal phase.

FIG. 11 is a diagram illustrating a bonding result in the case of laminating with each laser power.

FIG. 12 is a diagram illustrating results of measurement of Vickers hardness of the composite metal phase.

FIGS. 13A to 13C is a diagram illustrating another producing process for forming the first layer made of the composite metal phase.

FIGS. 14A to 14C is a diagram illustrating another producing process for forming the first layer made of the composite metal phase.

FIGS. 15A to 15E is a diagram illustrating a producing process of a composite metal material for forming the first layer and the second layer made of the composite metal phase.

FIG. 16 is a diagram illustrating a bonding result in the case of laminating with a laser power.

FIG. 17 is a diagram illustrating results of measurement of the Vickers hardness of the composite metal phase.

FIGS. 18A to 18E is a diagram illustrating a producing process for forming a first layer, a second layer and a third layer made of a composite metal phase.

FIG. 19 is a diagram illustrating a bonding result in the case of laminating with a laser power.

FIG. 20 is a diagram illustrating results of measurement of the Vickers hardness of the composite metal phase.

FIGS. 21A to 21E is an explanatory diagram of the case of processing the composite metal material in a fin shape.

FIG. 22 is a schematic diagram of an electronic device using the composite metal material.

### MODE FOR CARRYING OUT THE INVENTION

Hereinafter, embodiments of the present invention will be described with reference to the drawings. In each figure, the same configurations are denoted by the same reference numerals.

Provided is a novel metal (composite metal material) in which, in copper (Cu) having a high thermal conductivity and an iron (Fe)-based alloy having a high strength and a low thermal expansion coefficient, corresponding metal structures are uniformly dispersed. For example, in the case of ordinary alloy production of casting or the like, it is difficult to produce an alloy of Cu and Fe.

This is because, since the Cu and the Fe are systems that separate two phases, even through Cu and Fe are mixed in a melted state, the Cu and the Fe are not mixed with each other during solidification, and the structure form in which the Cu phase and the Fe phase are separated is formed. This is a phenomenon that occurs in casting and the like because the time from melting to solidification is long. For this reason, if solidification can be achieved instantaneously in a sufficiently stirred state during melting of the Cu and the Fe, a composite metal structure of the Cu and the Fe can be formed in such a form in which the Cu and the Fe are uniformly dispersed without causing two-phase separation in terms of macroscopic points.

As a method of intentionally controlling the supply amounts of different kinds of metal powders and melting the supplied metal powders with laser light to produce a molded object, there is a Laser Metal Deposition (LMD) method. This method is known as a three-dimensional metal laminating shaping method. Since a plurality of types of metal powder can be melted at the same time and only the powder supply portion is melted by the laser light, melting and solidification of the metal material occur instantaneously.

In this technology, a novel composite metal is produced by using the instant melting and solidification in accordance with the LMD method. In addition, since the supply amounts of different kinds of metal powders can be controlled, it is possible to laminate layers having different characteristics.

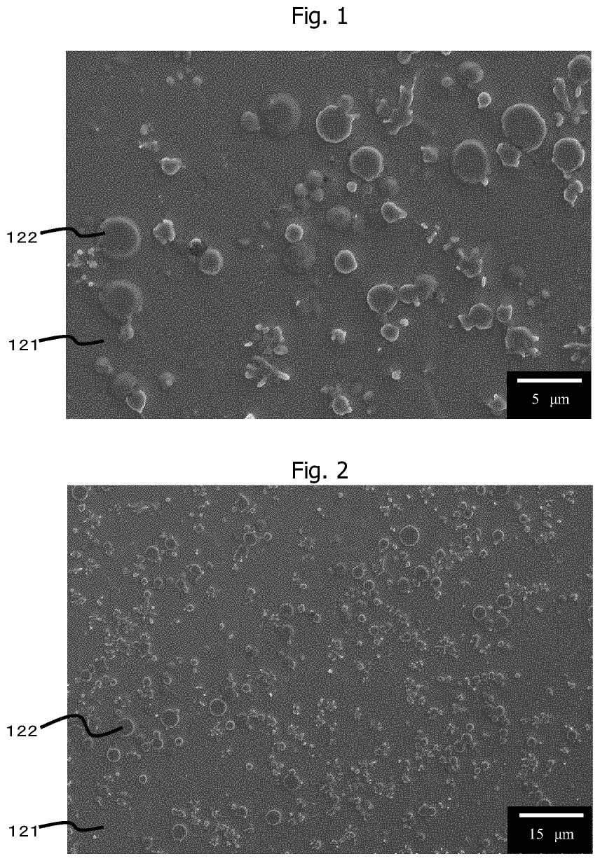

FIG. 1 is a photograph of high-magnification observation of a metal structure of a first layer made of a composite metal phase. The composite metal phase is configured with a Cu-rich phase 121 and an Fe-rich phase 122 and is formed in such a form which the Fe-rich phases 122 are spherically dispersed in the Cu-rich phase 121.

FIG. 2 is a photograph of low-magnification observation of the metal structure of the first layer made of the composite metal phase. Although there are Fe-rich phases 122 having various grain sizes, it can be seen that the metal structure is formed in such a form which the Fe-rich phases 122 are spherically dispersed in the Cu-rich phase 121 as in FIG. 1. The Fe-rich phases 122 are independently dispersed in the Cu-rich phase 121, so that it is possible to have a homogeneous metal structure with small anisotropy.

In addition, by dispersing the Fe-rich phases 122 in a matrix of the Cu-rich phase 121, it is possible to exhibit dispersion-enhanced alloy characteristics, and it is possible to improve the strength of the Cu matrix alloy. In addition, the Fe-rich phase 122 is an Fe-based alloy (SUS material) containing Ni, Cr, Co, and the like in a base of Fe, and it is possible to form a phase having a lower thermal expansion coefficient than Cu. That is, it is possible to lower the thermal expansion coefficient than that of Cu by dispersing the Fe-rich phase 122 having a thermal expansion coefficient lower than that (16.7 ppm/° C.) of Cu in a matrix of the Cu-rich phase 121.

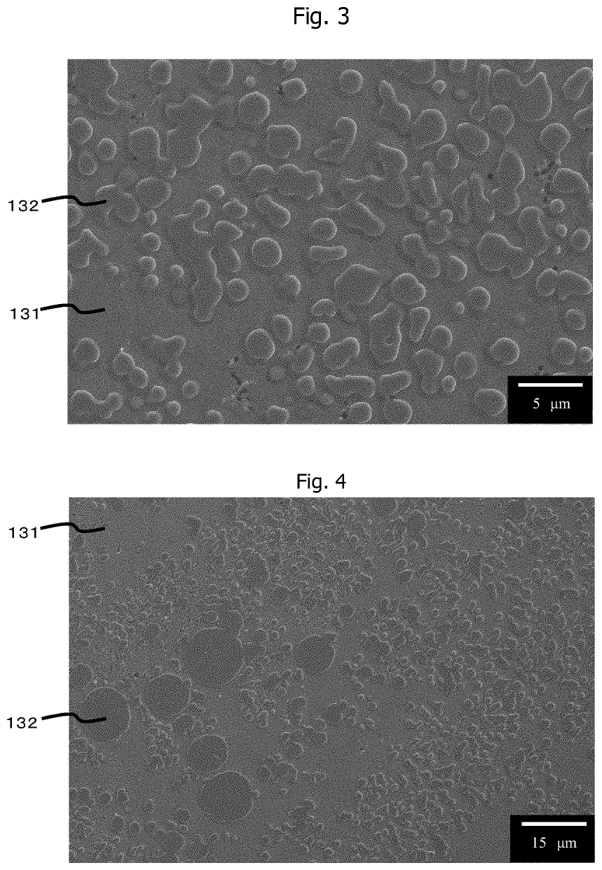

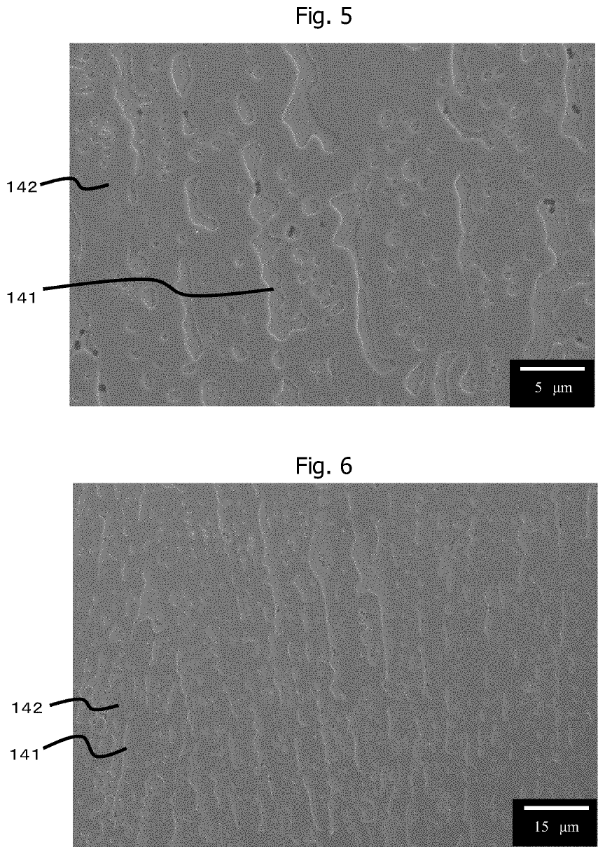

In the present technology, since Cu and Fe-based alloys are melted and solidified simultaneously by the LMD, the component of the Fe-based alloy is solid-dissolved even in the Cu. The phases in which the component of the Fe-based alloy is solid-dissolved in the Cu are collectively referred to as a Cu-rich phase, and the Cu-rich phase becomes a phase in which the Cu content is 85 wt % or more. As a representative alloy of the Fe-based alloys, SUS materials configured with Fe and Cr or Fe, Cr, and Ni as main components may be exemplified. The Cu-rich phase 121 in FIG. 1 has a Cu content of 93.4 wt % or more, a Cu-rich phase 131 in FIG. 3 has a Cu content of 90.3 wt %, and a Cu-rich phase 141 in FIG. 5 has a Cu content of 87.2 wt %. This denotes that the Cu-rich phase has a Cu content of substantially more than 85 wt % in consideration of variations in the analysis values. The present inventor confirmed that physical properties different from those of pure Cu were obtained by solid-dissolving other elements in the Cu, but if the Cu content is 85 wt % or more, sufficient composite effect was exhibited as in Examples described later.

In addition, the Fe-rich phase refers to an Fe-based alloy containing Fe as a main component and having an Fe content exceeding 50 wt %.

In addition, the powder supply at the time of laminating can be freely selected, but the powder supply at the time of laminating in FIGS. 1 and 2 is 75 wt % of Cu powder and 25 wt % of Fe-based alloy powder.

FIG. 3 and FIG. 4 are photographs of the observation results of the metal structure in a case where the powder supply amounts of Cu and Fe-based alloy are changed. By increasing the proportion of the powder amount of the Fe-based alloy as compared with FIGS. 1 and 2, the proportion of the Fe-rich phases 132 independently dispersed in the Cu-rich phase 131 is increased. In addition, the powder supply amounts in FIGS. 3 and 4 are 50 wt % of Cu powder and 50 wt % of Fe-based alloy powder.

FIGS. 5 and 6 show results of observing the structure of a composite metal alloy when the Cu powder is set to 25 wt % and the Fe-based alloy powder is set to 75 wt %. The form is obtained in which the Cu-rich phases 141 are dispersed in the Fe-rich phase 142 by increasing the proportion of the Fe-based alloy powder amount. In addition, as the dispersed shape, a portion of the Cu-rich phase 141 is spherical, and a portion of the Cu-rich phase 141 is formed in a columnar shape with respect to the lamination direction (the direction perpendicular to the longitudinal direction of the drawings), and thus, it can be seen that anisotropy is exhibited. An isotropic structure is preferable, but in a case where it is uniformly dispersed, the composite metal alloy is not always necessary to have an isotropic structure.

In the cases of FIG. 5 and FIG. 6, since the Cu-rich phase 141 is oriented, the thermal conductivity in the lamination direction (longitudinal direction of the drawings) is higher than that of a normal Fe-based alloy. That is, in a case where a heat sink for cooling the semiconductor chip is assumed, since the composite metal alloy has an anisotropic structure that is advantageous in the lamination direction, it is possible to obtain the composite metal alloy having excellent thermal conductivity.

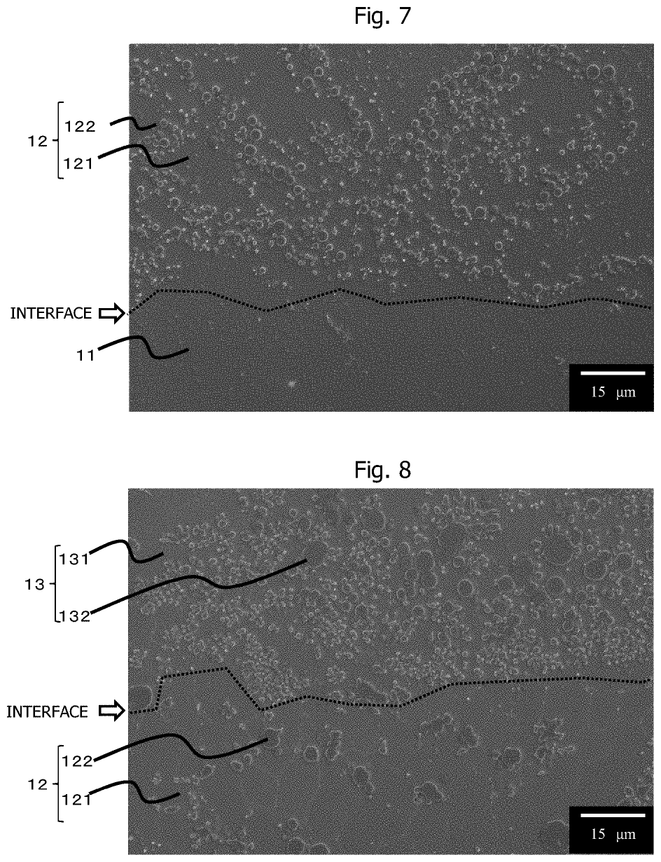

FIG. 7 shows a bonding interface in a case where a composite metal phase 12 is laminated on the pure Cu 11 with a mixing ratio of 75 wt % of Cu powder and 25 wt % of Fe-based alloy powder.

FIG. 8 shows the bonding interface in a case where a composite metal phase 13 in which the powder supply amount is 50 wt % of Cu powder and 50 wt % of Fe-based alloy powder is laminated on the composite metal phase 12 laminated with a mixing ratio of 75 wt % of Cu powder and 25 wt % of Fe-based alloy powder.

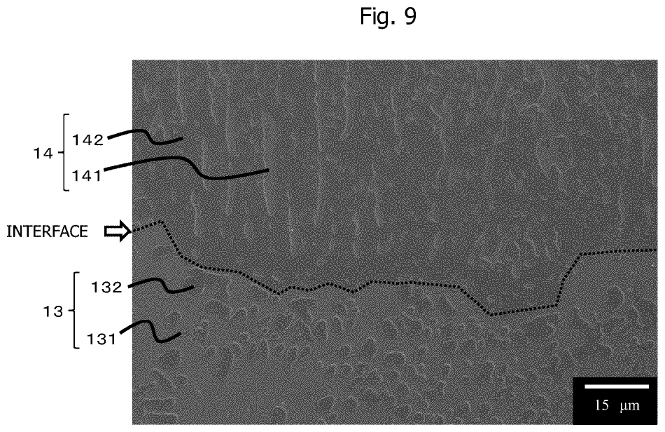

FIG. 9 shows the bonding interface in a case where a composite metal phase 14 in which the power supply amount is 25 wt % of Cu powder and 75 wt % of Fe-based alloy powder is laminated on the composite metal phase 13 laminated with a mixing ratio of 50 wt % of Cu powder and 50 wt % of Fe-based alloy powder. In any of the cases shown in FIG. 7 to FIG. 9, it is shown that the-rich phases are dispersed in an independent form in a spherical or columnar shape, and the respective layers are metallically bonded not on a simple straight bonding surface but on a complicated bonding surface. In this manner, by gradually reducing the content of Cu powder for each layer formation of the composite metal phase, it is possible to form a structure of alleviating the influence of thermal stress at the time of bonding members having greatly different coefficients of thermal expansion such as semiconductor chips. In the above example, the Cu powder and the Fe-based alloy powder are allowed to have different contents, and the content of the Cu powder is gradually decreased (graded) in order, but for example, it goes without saying that it is possible to form the composite metal phase on the pure Cu 11 with a mixing ratio of 25 wt % of Cu powder and 75 wt % of Fe-based alloy powder.

In the case of the LMD method, it is preferable that the laser power is 800 to 2000 W in order to achieve good metal bonding with few defects where the formation state of the laminate is changed by changing the laser power. In a case where the laser power is 800 W or less, unmelted portions are generated, and voids are generated in the laminated body. In a case where the laser power is 2000 W or more, the melting range is widened during the lamination, so that rapid cooling is difficult, and thus, it is difficult to obtain a uniform composite metal structure.

### Example 1

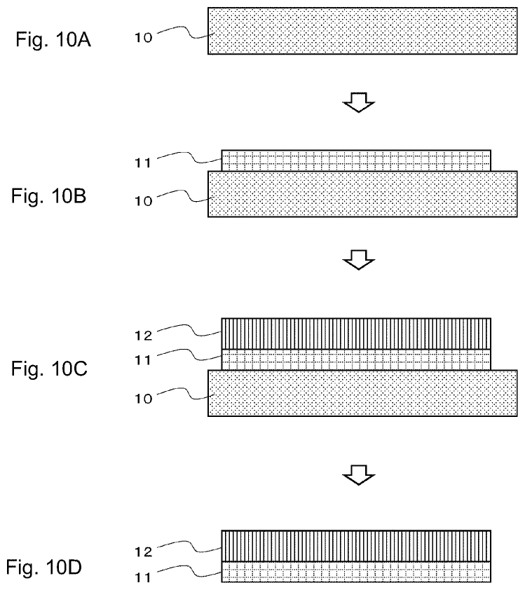

FIGS. 10A to 10D illustrates a producing process flow for forming the first layer 12 which is the composite metal phase configured with the Cu-rich phase 121 and the Fe-rich phase 122 in Example 1. (a) First, the Fe-based base material 10 is mounted inside the LMD device. (b) After that, a Cu phase 11 (ideally, the content of the Cu powder is 100 wt %, but in some cases, the Cu powder may contain some impurities, and thus, the Cu content is 98 wt % or more) is formed by performing laser irradiation while supplying the Cu powder on the Fe-based base material 10. (c) Next, the composite metal phase 12 is formed by performing laser irradiation while supplying the powder (a mixed powder of the Cu powder and the Fe-based alloy powder) on the Cu phase 11 with a predetermined ratio of the content of the Cu powder and the content of the Fe-based alloy powder in predetermined proportions, for example, with a mixing ratio of 75 wt % of Cu powder and 25 wt % of Fe-based alloy powder. The Cu phase 11 and the composite metal phase are metallically bonded at the complicated bonding surfaces shown in FIGS. 7 to 9. (d) After the lamination, a laminated body including the Cu phase 11 having a high thermal conductivity and the composite metal phase 12 is obtained by mechanically cutting the Fe-based base material 10.

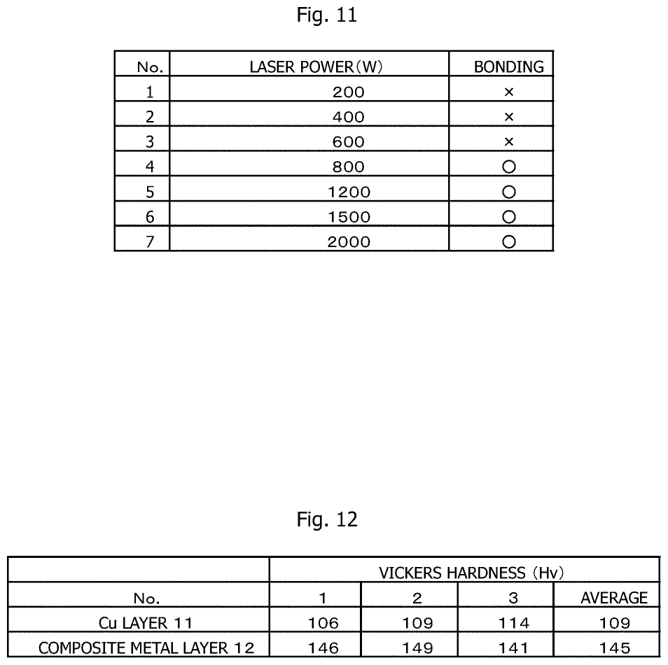

FIG. 11 shows the bonding result in a case where lamination is performed at each laser power. In a case where the laser power is less than 800 W, unmelting of the powder occurs due to insufficient power, and in addition to generation of voids in the phase, the interface between the Cu phase 11 and the composite metal phase 12 cannot be bonded. In a case where the laser power is 800 W or more, the Cu powder and the Fe-based alloy powder are melted and thus, it is possible to achieve strong bonding. In addition, FIGS. 1, 2, and 7 are the observation results of the structures in a case where lamination is performed at a laser power of 2000 W.

FIG. 12 shows the results of measurement of the Vickers hardness of the Cu phase 11 and the composite metal phase 12 (including the Cu-rich phase 121 and the Fe-rich phase 122) illustrated in FIGS. 10A to 10D. The Cu phase 11 has an average Vickers hardness of 109, and the composite metal phase 12 has an average Vickers hardness of 145. It can be confirmed that the strength of the composite metal phase 12 has increased due to the dispersion of the Fe-rich phase. In addition, the diagonal length of the Vickers indenter is larger than 20 μm, and the measurement is performed at a location including both the Cu-rich phase 121 and the Fe-rich phase 122.

In Example 1, the Cu phase 11 is formed by performing laser irradiation while supplying the Cu powder on the Fe-based base material 10, and the composite metal phase 12 is further formed on the Cu phase 11. After that, as a high thermal conductive layer, the Fe-based base material 10 is cut in such a form that the Cu phase 11 and the composite metal phase 12 remain.

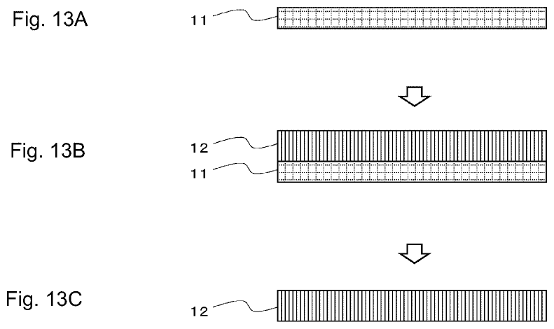

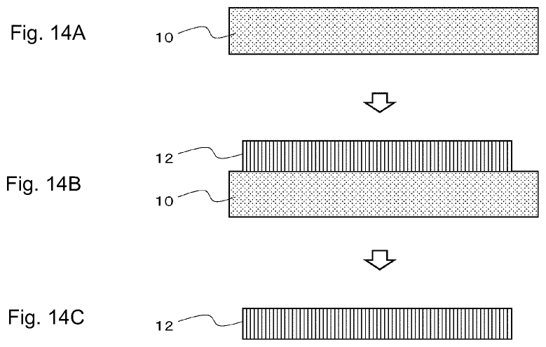

As illustrated in FIGS. 13A to 13C and FIGS. 14A to 14C, the Cu phase 11 and the composite metal phase 12 may not necessarily remain. That is, as illustrated in FIGS. 14A to 14C, as a producing process, the composite metal phase 12 is directly formed on the Fe-based base material 10 and, after that, the Fe-based base material 10 is cut, or as illustrated in FIGS. 13A to 13C, it goes without saying that a single composite metal phase 12 can be obtained by directly forming the composite metal phase 12 on the Cu phase 11 and, after that, cutting the Cu phase 11.

### Example 2

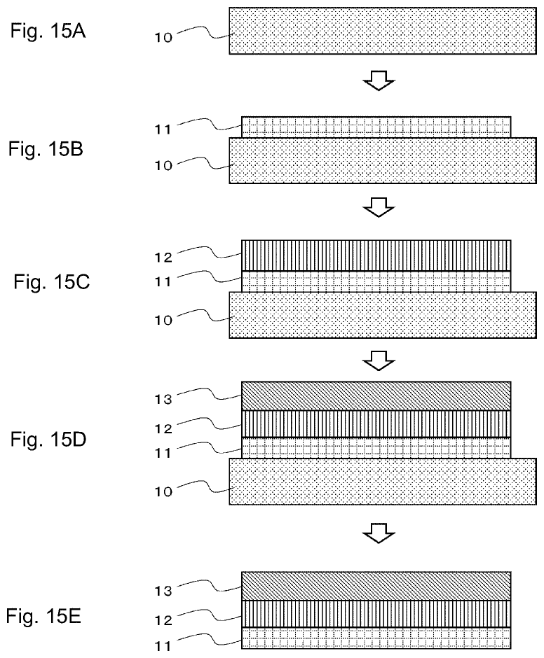

FIGS. 15A to 15E illustrates the producing process of the composite metal material which forms the first layer and the second layer which are made of a composite metal phase in Example 2.

(a) First, the Fe-based base material 10 is mounted inside the LMD device. (b) After that, the Cu phase 11 (ideally, the content of the Cu powder is 100 wt %, but in some cases, the Cu powder may contain some impurities, and thus, the Cu content is 98 wt % or more) is formed by performing laser irradiation while supplying the Cu powder on the Fe-based base material 10.

(c) Next, the composite metal phase 12 is formed by performing laser irradiation while supplying the powder (a mixed powder of the Cu powder and the Fe-based alloy powder) on the Cu phase 11 with a predetermined ratio of the content of the Cu powder and the content of the Fe-based alloy powder in predetermined proportions, for example, with a mixing ratio of 75 wt % of Cu powder and 25 wt % of Fe-based alloy powder. The Cu phase 11 and the composite metal phase are metallically bonded at the complicated bonding surfaces shown in FIGS. 7 to 9. (d) In addition, the composite metal phase 13 is formed by performing laser irradiation while supplying powder on the composite metal phase 12 with a mixing ratio of 50 wt % of Cu powder and 50 wt % of Fe-based alloy powder. (e) After the lamination, a laminated body including the Cu phase 11 having a high thermal conductivity, the composite metal phase 12, and the composite metal phase 13 is obtained by mechanically cutting the Fe-based base material 10.

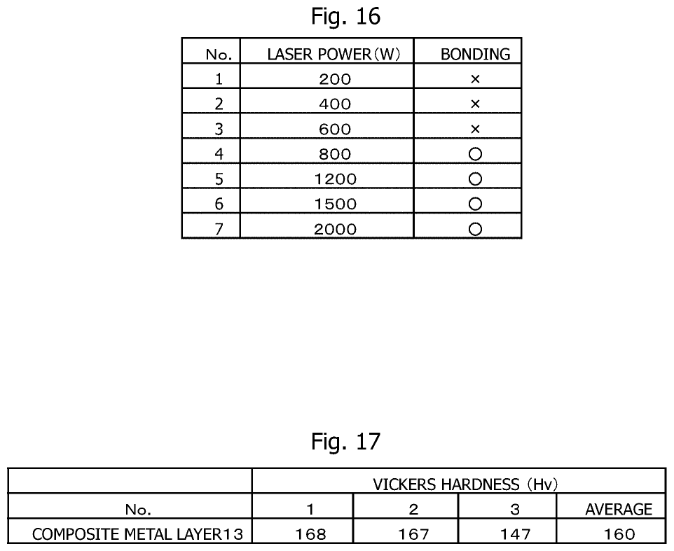

FIG. 16 shows the bonding result in a case where lamination is performed at each laser power. In a case where the laser power is less than 800 W, unmelting of the powder occurs due to insufficient power, and in addition to generation of voids in the phase, the interface between the Cu phase 11 and the composite metal phase 12 cannot be bonded. In a case where the laser power is 800 W or more, the Cu powder and the Fe-based alloy powder are melted, and thus, it is possible to achieve strong bonding. That is, it is possible to perform lamination under the same conditions as those in Example 1. In addition, FIGS. 3, 4, and 8 are the observation results of the structures in a case where the composite metal phase 13 of Example 2 is laminated at 2000 W.

FIG. 17 shows the results of measurement of the Vickers hardness of the composite metal phase 13 (including the Cu-rich phase 131 and the Fe-rich phase 132) of the composite metal material having a plurality of composite metal phases produced by the method illustrated in FIGS. 15A to 15E. The average Vickers hardness of the composite metal phase 13 is 160, and it can be seen that the strength is higher than that of the composite metal phase 12. In addition, the diagonal length of the Vickers indenter is larger than 20 μm, and the measurement is performed at a location including both the Cu-rich phase 121 and the Fe-rich phase 122.

### Example 3

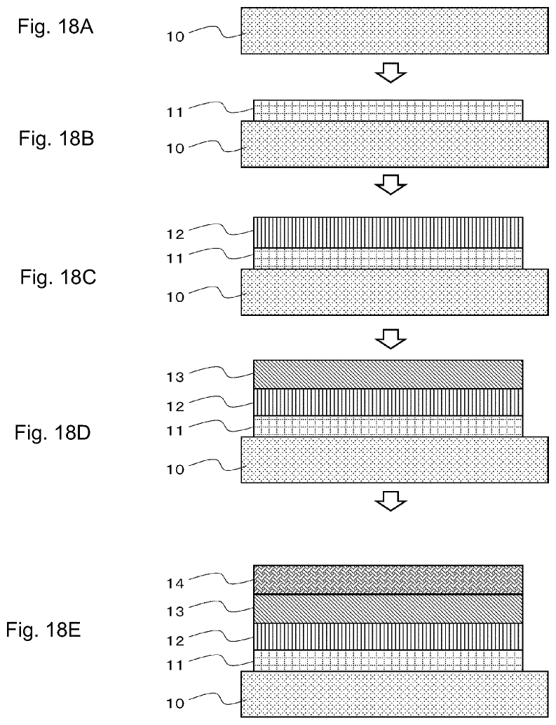

FIGS. 18A to 18E illustrates a producing process of Example 3 in which three composite metal phases of the first layer to the third layer are formed.

(a) First, the Fe-based base material 10 is mounted inside the LMD device. (b) After that, the Cu phase 11 (ideally, the content of the Cu powder is 100 wt %, but in some cases, the Cu powder may contain some impurities, and thus, the Cu content is 98 wt % or more) is formed by performing laser irradiation while supplying the Cu powder on the Fe-based base material 10. (c) Next, the composite metal phase 12 is formed by performing laser irradiation while supplying the powder (a mixed powder of the Cu powder and the Fe-based alloy powder) on the Cu phase 11 with a predetermined ratio of the content of the Cu powder and the content of the Fe-based alloy powder in predetermined proportions, for example, with a mixing ratio of 75 wt % of Cu powder and 25 wt % of Fe-based alloy powder. The Cu phase 11 and the composite metal phase are metallically bonded at the complicated bonding surfaces shown in FIGS. 7 to 9. (d) In addition, the composite metal phase 13 is formed by performing laser irradiation while supplying powder on the composite metal phase 12 with a mixing ratio of 50 wt % of Cu powder and 50 wt % of Fe-based alloy powder. (e) In addition, the composite metal phase 14 is formed by performing laser irradiation while supplying powder on the composite metal phase 13 with a mixing ratio of 25 wt % of Cu powder and 75 wt % of Fe-based alloy powder. After the lamination, a laminated body (not illustrated) including the Cu phase 11 having a high thermal conductivity, the composite metal phase 12, the composite metal phase 13, and the composite metal phase 14 is obtained by mechanically cutting the Fe-based base material 10. The Cu phase 11, the composite metal phase 12, and the composite metal phase 13 are metallically bonded at the complicated bonding surfaces shown in FIGS. 7 to 9.

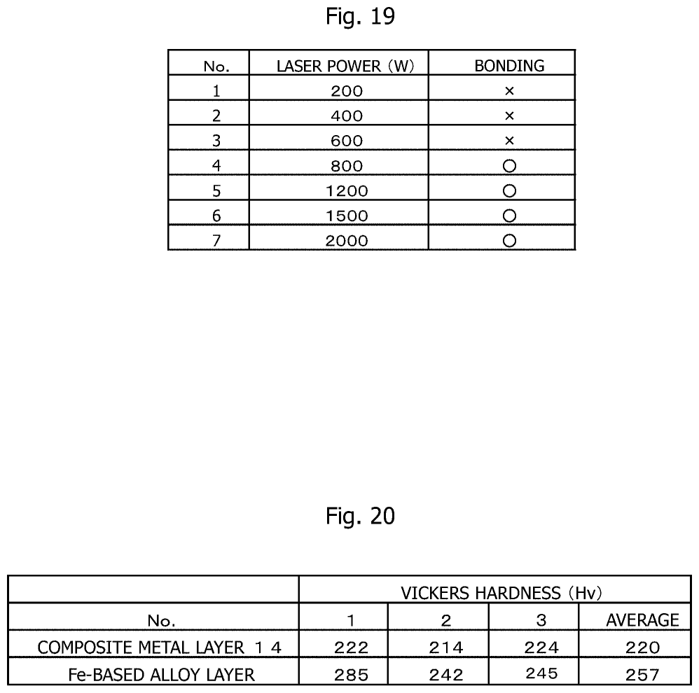

FIG. 19 shows the bonding result in a case where lamination is performed at each laser power. In a case where the laser power is less than 800 W, unmelting of the powder occurs due to insufficient power, and in addition to generation of voids in the layer, and the interface between the Cu phase 11 and the composite metal phase 12 cannot be bonded. In a case where the laser power is 800 W or more, the Cu powder and the Fe-based alloy powder are melted, and thus, it is possible to achieve strong bonding. That is, it is possible to perform lamination under the same conditions as those in Examples 1 and 2. In addition, FIGS. 5, 6, and 9 are the observation results of the structures in a case where the composite metal phase 14 of Example 3 is laminated at 2000 W.

FIG. 20 shows the results of the Vickers hardness of the composite metal phase 14 (including the Cu-rich phase 141 and the Fe-rich phase 142) of the composite metal material having a plurality of composite metal phases produced by the method illustrated in FIGS. 18A to 18E. The average Vickers hardness of the composite metal phase 14 is 220, and it can be seen that the strength is higher than those of the composite metal phase 12 and the composite metal phase 13. In addition, the average value of the Vickers hardness of the Fe-based alloy phase is 257, and since the Vickers hardness changes in a gradient manner, the effect of composition gradient is exhibited. In addition, the diagonal length of the Vickers indenter is larger than 20 μm, and the measurement is performed at a location including both the Cu-rich phase 121 and the Fe-rich phase 122.

As can be seen from Example 1, Example 2 and Example 3, according to the present technology, it can be seen that it is possible to disperse and mix the Cu and the Fe-based alloy and to have a composite effect. That is, by changing the mixing ratio of the Cu powder and the Fe powder, it is possible to produce a composite metal material having a predetermined strength. In addition, by changing the mixing ratio of Cu powder and the Fe powder, in the produced composite metal material, the Fe-rich phase in the Cu-rich phase or the Cu-rich phase in the Fe-rich phase can be independently dispersed, so that a composite metal material having a desired thermal conductivity can be obtained.

In Example 2 and Example 3, the composite metal phase is laminated in such a form that the proportion of Cu is gradually increased. For the purpose of alleviation of thermal stress and the like, it is possible to reduce the effect of the thermal stress at the bonding interface by setting the mixing ratio (gradient composition) in which the proportion of Cu is gradually increased.

In addition, the gradient composition may not be necessarily required as in Example 3, and it goes without saying that the laminated configuration of the composite metal phase can be freely selected according to the applications. In a case where a processing step such as cutting is included, the workability is changed depending on the content ratios of the Cu-rich phase and the Fe-rich phase. Therefore, by appropriately selecting the laminated configuration of the composite metal phase, it is possible to take the laminated configuration in consideration of the workability.

For example, as seen in Example 3, the composite metal phase 12 may be formed by performing laser irradiation while supplying powder on the Cu phase 11 with a mixing ratio of 75 wt % of Cu powder and 25 wt % of Fe-based alloy powder, after that, the composite metal phase 14 may be laminated by performing laser irradiation while supplying powder on the composite metal phase 12 with a mixing ratio of 25 wt % of Cu powder % and 75 wt % of Fe-based alloy powder, and furthermore, the composite metal phase 13 may be formed by performing laser irradiation while supplying powder on the composite metal phase 14 with a mixing ratio of 50 wt % of Cu powder and 50 wt % of Fe-based alloy powder.

### Example 4

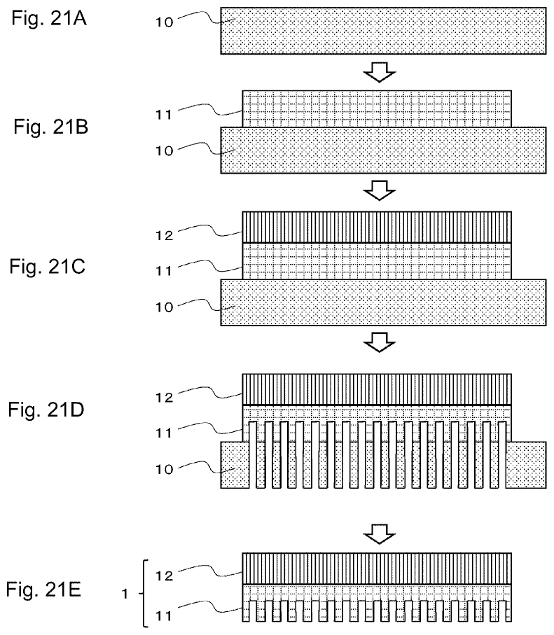

It is possible to use these novel composite metal materials for heat sinks and molds for semiconductor chips. FIGS. 21A to 21E illustrates an explanatory view of the case of processing the composite metal material obtained in Examples 1 to 3 in a fin shape.

FIGS. 21A to 21E illustrates a step of processing the Cu phase 11 of a high thermal conductive portion into a fin shape by mechanically grooving after producing the composite metal material by the method illustrated in FIGS. 10A to 10D. In FIGS. 21A to 21C similarly to FIGS. 10A to 10C, (a) First, the Fe-based base material 10 is mounted inside the LMD device. Then, (b) the Cu phase 11 (ideally, the content of the Cu powder is 100 wt %, but in some cases, the Cu powder may contain some impurities, and thus, the Cu content is 98 wt % or more) is formed by performing laser irradiation while supplying the Cu powder on the Fe-based base material 10. Next, (c) the composite metal phase 12 is formed by performing laser irradiation while supplying the powder (a mixed powder of the Cu powder and the Fe-based alloy powder) on the Cu phase 11 with a predetermined ratio of the content of the Cu powder and the content of the Fe-based alloy powder in predetermined proportions, for example, with a mixing ratio of 75 wt % of Cu powder and 25 wt % of Fe-based alloy powder. The Cu phase 11 and the composite metal phase are metallically bonded at the complicated bonding surfaces illustrated in FIGS. 7 to 9. Next, (d) a fin-attached heat sink is formed by machining. Finally, (e) a laminated body including the Cu phase 11 having a high thermal conductivity and the composite metal phase 12 of the fin-attached heat sink is obtained by mechanically cutting the Fe-based base material 10. The producing process of FIGS. 21A to 21E can be similarly applied to the processes illustrated in FIGS. 13A to 13C to FIGS. 15A to 15E and FIGS. 18A to 18E in addition to the process illustrated in FIGS. 10A to 10D.

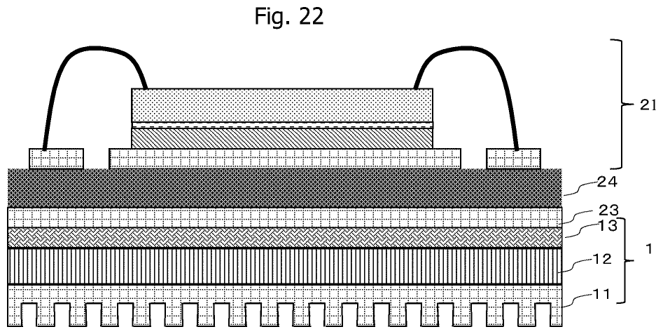

FIG. 22 illustrates a schematic diagram of an electronic device in which a fin-attached heat sink 1 made of a composite metal material having composite metal phases 11, 12, and 13 is bonded to a semiconductor element 21. The semiconductor element 21 is mounted on the composite metal material via an insulating material 24 and a bonding agent 23.

According to the composite metal materials of Examples 1 to 4, it is possible to prevent the electronic components from being destructed due to thermal stress by reducing the proportion of Cu having a high thermal conductivity for each layer.

In addition, since the composite metal materials according to Examples 1 to 4 can be configured in a state where the Cu-rich phase is independently dispersed, the thermal conductivity is good, and it is possible to efficiently dissipate the heat of the electronic components such as the semiconductor chip 21 serving as the heat dissipation source.

Furthermore, by controlling the proportion of the Fe-rich phase, it is possible to secure a desired strength.

In addition, although not necessarily formed in a fin shape, even in a case where the Cu phase 11 and the composite metal phase 12 are bonded in a plate shape as illustrated in FIGS. 18A to 18E, an excellent effect can be exhibited.

Since the composite metal materials of Examples 1 to 4 with a homogeneous metal composition having little anisotropy can be formed by independently dispersing the Cu-rich phase and the Fe-rich phase, with respect to molds used not only for electronic devices but also for industrial applications, the composite metal materials can be used as members having a high thermal conductivity while maintaining the strength of the molds.

As described above, since the composite metal materials described in the embodiments have an excellent composite effect in which the thermal conductivity and strength can be adjusted, the composite metal materials can be applied to various products that are desired to have both good thermal conductivity and good strength without limitation to the electronic devices and the molds.

### REFERENCE SIGNS LIST

1 Fin-attached heat sink
10 Fe-based alloy base material
11 Cu material
12 to 13 Composite metal phase
21 Semiconductor chip
121 Cu-rich phase
122 Fe-rich phase
131 Cu-rich phase
132 Fe-rich phase
141 Cu-rich phase
142 Fe-rich phase

1. A composite metal material having a Cu-rich phase and an Fe-rich phase, wherein the composite metal material has a composite metal phase in which the Fe-rich phases are independently dispersed in the Cu-rich phase.

2. The composite metal material according to claim 1,
wherein the Cu-rich phase has a Cu content of more than 85 wt %, and
wherein the Fe-rich phase has an Fe content of more than 50 wt %.

3. The composite metal material according to claim 1, wherein the Cu-rich phase contains 15 wt % or less of at least one kind of elements consisting of Fe, Cr, Ni, and Co.

4. The composite metal material according to claim 2, having a Cu phase of which the Cu content of Cu metallically bonded to the composite metal phase via a bonding surface is 98 wt % or more.

5. The composite metal material according to claim 4, wherein the composite metal phase has a composite metal phase configured with at least two layers, has a first layer made of a composite metal phase including a predetermined proportion of Fe-rich phases and a second layer made of a composite metal phase having more Fe-rich phases than the first layer, one side of the first layer is metallically bonded to the Cu phase, and the other side of the first layer is metallically bonded to the second layer.

6. The composite metal material according to claim 4, wherein the composite metal phase has a composite metal phase configured with at least three layers, has a first layer made of a composite metal phase including a predetermined proportion of Fe-rich phases, a second layer made of a composite metal phase having more Fe-rich phases than the first layer, and a third layer made of a composite metal phase which has a larger proportion of Fe-rich phase than the second layer and in which a portion of the Cu-rich phase is dispersed in a columnar shape in the Fe-rich layer, one side of the first layer is metallically bonded to the Cu phase, the other side of the first layer is metallically bonded to the second layer, and the other side of the second layer is metallically bonded to the third layer.

7. The composite metal material according to claim 2,
wherein the composite metal phase has a composite metal phase configured with at least two layers, has a first layer made of a composite metal phase including a predetermined proportion of Fe-rich phases and a second layer made of a composite metal phase having more Fe-rich phases than the first layer, one side of the first layer is metallically bonded to the Cu phase, and the other side of the first layer is metallically bonded to the second layer, and
wherein the composite metal material has a fin-shaped groove in the composite metal phase of two or more layers.

8. An electronic device comprising:
a composite metal material having a composite metal phase in which Fe-rich phases are independently dispersed in a Cu-rich phase; and
a semiconductor element mounted on the composite metal material.

9. A method for producing a composite metal material having a Cu-rich phase and an Fe-rich phase, the method comprising forming a composite metal phase by performing laser irradiation while supplying predetermined proportions of Cu powder and Fe-based alloy powder.

10. The method for producing the composite metal material according to claim 9,
wherein a predetermined proportion of the composite metal phase is set as a first layer, and
wherein a composite metal phase of a second layer is formed by performing laser irradiation while supplying a mixed powder containing a larger content proportion of Fe-based alloy powder than the first layer.

11. The method for producing the composite metal material according to claim 10, wherein a composite metal phase of a third layer is formed by performing laser irradiation while supplying a mixed powder containing a larger content proportion of Fe-based alloy powder than the second layer.

12. The method for producing the composite metal material according to claim 9, wherein a laser power of the laser irradiation is 800 to 2000 W.
